(19) United States
(12) Patent Application Publication
(10) Pub. No.: US 2026/0187325 A1
(43) Pub. Date: Jul. 2, 2026

(54) SYSTEM AND METHOD FOR EXHAUST EMISSION MODELING AND ANALYSIS OF MUNICIPAL SOLID WASTE INCINERATION PROCESS

(71) Applicant: BEIJING UNIVERSITY OF TECHNOLOGY, Beijing (CN)

(72) Inventors: Jian Tang, Beijing (CN); Tianzheng Wang, Beijing (CN); Heng Xia, Beijing (CN); Junfei Qiao, Beijing (CN)

(73) Assignee: BEIJING UNIVERSITY OF TECHNOLOGY, Beijing (CN)

(21) Appl. No.: 19/533,385

(22) Filed: Feb. 9, 2026

Related U.S. Application Data
(63) Continuation of application No. PCT/CN2024/090317, filed on Apr. 28, 2024.

(30) Foreign Application Priority Data
Nov. 3, 2023 (CN) 202311459798.1

(51) Int. Cl. G06F 30/28

(52) U.S. Cl. CPC G06F 30/28

(57) ABSTRACT

A system and a method for exhaust emission modeling and analysis of a municipal solid waste incineration process are provided. The system includes: a module for building a whole-process numerical simulation model under reference operating conditions by coupling multiple software, a module for acquiring simulation mechanism data under multiple operating conditions, a module for building a MIMO-LRDT-based exhaust emission model, and a module for single/double-factor-based exhaust emission analysis, where the module for building the whole-process numerical simulation model under reference operating conditions by coupling multiple software is connected to the module for acquiring simulation mechanism data under multiple operating conditions; the module for acquiring simulation mechanism data under multiple operating conditions is connected to the module for building the MIMO-LRDT-based exhaust emission model; and the module for building the MIMO-LRDT-based exhaust emission model is connected to the module for single/double-factor-based exhaust emission analysis.

### CROSS REFERENCE TO THE RELATED APPLICATIONS

This application is the continuation application of International Application No. PCT/CN2024/090317, filed on Apr. 28, 2024, which is based upon and claims priority to Chinese Patent Application No. 202311459798.1, filed on Nov. 3, 2023, the entire contents of which are incorporated herein by reference.

### TECHNICAL FIELD

The present invention relates to the technical field of municipal solid waste incineration, and in particular to a system and method for exhaust emission modeling and analysis of a municipal solid waste incineration process.

### BACKGROUND

The production of municipal solid waste (MSW) is gradually increasing with the acceleration of economic development and urbanization, and its annual global production will reach 3.4 billion tons in 2050. The MSW incineration (MSWI) technology converts wastes to energy (WTE) by means of process stages such as fermentation, combustion, heat exchange and purification, and it has been widely applied due to its advantages of harmlessness, reduction, and resource utilization. The MSWI technology in China is largely introduced from Europe, Japan and other developed countries where an automatic combustion control (ACC) system is used for steady operation. However, the problems of high moisture, low calorific value and complex components of MSWs in China have limited the actual application of the ACC system in China. At present, field experts on the actual industrial site combine a discrete control system (DCS), flame video images, team/group job records and other multi-modal information, and they depend on their experience to manually set the parameters of manipulated variables of “air and material distribution” for problems such as abnormal furnace temperature and excessive exhaust emission, in order to achieve the safe and stable operation of the MSWI process. This manual operating mode has serious problems such as randomness, hysteresis, limited energy of personnel and discrepancy in expert experience, making it difficult to ensure the long-term stable operating condition of an MSWI power plant. Therefore, it is necessary to study the mapping relationship between the manipulated variables of “air and material distribution” and exhaust emission to support the control strategy of the MSWI process.

As a typical process flow, the industrial MSWI process involves complex physicochemical reactions having numerous variables that are coupled with each other, making it difficult to build an accurate mathematical model. At present, numerical simulation software such as fuel layer interface code (FLIC), computational fluid dynamics (CFD) and Aspen Plus have become effective tools for analyzing the MSWI process due to their advantages such as efficiency, economy and ease in operation. Simulating with single numerical simulation software can hardly be used to effectively analyze the complex mapping relationship between the variables of “air and material distribution” and the exhaust emission concentration. Therefore, it is necessary to design a system and method for exhaust emission modeling and analysis of a municipal solid waste incineration process.

### SUMMARY

An object of the present invention is to provide a system and method for exhaust emission modeling and analysis of a municipal solid waste incineration process, to enable the exhaust emission modeling and analysis of the municipal solid waste incineration process.

To achieve the object above, the present invention provides the following solution.

A system for exhaust emission modeling and analysis of a municipal solid waste incineration process includes: a module for building a whole-process numerical simulation model under reference operating conditions by coupling multiple software, a module for acquiring simulation mechanism data under multiple operating conditions, a module for building a multiple-input multiple-output local regression decision tree (MIMO-LRDT)-based exhaust emission model, and a module for single/double-factor-based exhaust emission analysis, wherein the module for building the whole-process numerical simulation model under reference operating conditions by coupling multiple software is connected to the module for acquiring simulation mechanism data under multiple operating conditions, the module for acquiring simulation mechanism data under multiple operating conditions is connected to the module for building the MIMO-LRDT-based exhaust emission model, the module for building the MIMO-LRDT-based exhaust emission model is connected to the module for single/double-factor-based exhaust emission analysis;

the module for building the whole-process numerical simulation model under reference operating conditions by coupling multiple software is configured to build a whole-process numerical simulation model capable of fitting reference operating conditions on an industrial site;

the module for acquiring simulation mechanism data under multiple operating conditions is configured to enable the whole-process numerical simulation model to acquire simulation mechanism data under multiple operating conditions;

the module for building the MIMO-LRDT-based exhaust emission model is configured to build an exhaust emission model based on a MIMO-LRDT algorithm; and

the module for single/double-factor-based exhaust emission analysis is configured to perform single/double-factor analysis on a mapping relationship between manipulated variables and exhaust emissions concentration based on the exhaust emission model.

The present invention further provides a method for exhaust emission modeling and analysis of a municipal solid waste incineration process, which is applied to the system for exhaust emission modeling and analysis of the municipal solid waste incineration process ad described above, wherein the method includes the steps of:
step 1: building, based on a module for building a whole-process numerical simulation model under reference operating conditions by coupling multiple software, a whole-process numerical simulation model capable of fitting reference operating conditions on an industrial site;
step 2: acquiring, based on a module for acquiring simulation mechanism data under multiple operating conditions, simulation mechanism data under multiple operating conditions by means of the whole-process numerical simulation model;
step 3: building an exhaust emission model based on a MIMO-LRDT algorithm by means of a module for building a MIMO-LRDT-based exhaust emission model; and
step 4: performing single/double-factor analysis on a mapping relationship between manipulated variables and exhaust emissions concentration based on the exhaust emission model by means of the module for single/double-factor-based exhaust emission analysis.

Optionally, in step 1: building, based on the module for building the whole-process numerical simulation model under reference operating conditions by coupling multiple software, the whole-process numerical simulation model capable of fitting reference operating conditions on the industrial site specifically includes the steps of:
step 101: simulating a solid phase combustion process on a grate based on FLIC;
step 102: simulating a gas phase combustion process in a hearth based on Fluent; and
step 103: simulating waste heat exchange, flue gas cleaning and other processes based on Aspen Plus.

Optionally, in step 101, simulating the solid phase combustion process on the grate based on the FLIC is specifically as follows:
the solid phase combustion process on the grate is simulated by means of the FLIC, in which a solid-phase MSW combustion model, a basic conservation equation, and a component transfer and thermal radiation conversion equation are involved;
a solid phase MSW combustion process includes stages of water evaporation, volatile component precipitation, volatile component combustion, and coke oxidation, in which MSW is pushed by a feeder to the grate and undergo high-temperature thermal radiation in a furnace and from a furnace wall to gradually evaporate water at a rate of:

$${R}_{evp} = \{ \begin{matrix}{S}_{a} {h}_{s} ( {C}_{w , s} - {C}_{w , g} ) , & {T}_{s} < 100 °C . \\ {Q}_{cr} / {H}_{evp} , & {T}_{s} = 100 °C .\end{matrix} , \qquad ( 1 )$$

in which Rₑᵥₚ indicates a water evaporation rate, Sₐ indicates a particle surface area, hₛ indicates a convective mass transfer coefficient, C_{w,s} and C_{w,g} indicate a moisture content in the MSW and in a mixed gas respectively, Q_{cr} indicates absorbed heat in radiation and convective heat transfer processes, Hₑᵥₚ indicates absorbed heat required for water evaporation, and Tₛ indicates an MSW temperature; after the water evaporation is completed, the MSW reaches a temperature for volatile component precipitation, and a process of releasing main components is as follows:

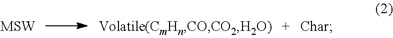

a volatile gas is mixed with air and then combusted, with corresponding

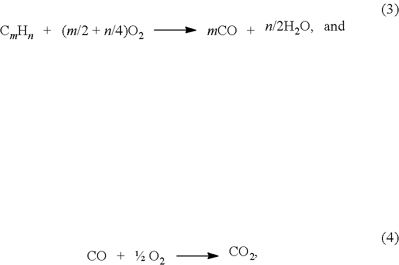

with a combustion rate being a minimum value between a kinetic rate and a mixing rate; and the MSW gradually turns into coke along with the volatile component precipitation, and further react with air to produce CO and CO₂ as follows:

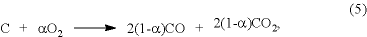

in which α indicates a stoichiometric coefficient, and 0.5≤α≤1.

Optionally, in step 102, simulating the gas phase combustion process in the hearth based on Fluent is specifically as follows:
by taking an FLIC output as a boundary condition of Fluent numerical simulation, a combustion component CmHn is substituted with CH₄ in the Fluent, and a gas phase component combustion equation is discretized and solved by using a second order upwind format and a semi-implicit method for pressure-linked equations (SIMPLE) algorithm, with a thermal radiation discrete ordinates (DO) model as follows:

$$\begin{matrix}∇ \cdot ( I ( r , s ) s ) + ( a + {σ}_{s} ) I ( r , s ) = {an}^{2} \frac{σ {T}^{4}}{π} \\ + \frac{{σ}_{s}}{4 π} {\int }_{0}^{4 π} I ( \vec{r} , \vec{s} ) Φ ( \vec{s} , {\vec{s}}^{′} ) d {Ω}^{′}\end{matrix} , \qquad ( 6 )$$

in which I indicates a radiation intensity, \vec{r} and \vec{s} indicate a position vector and a direction vector respectively, a indicates an absorption coefficient, σₛ indicates a diffusion coefficient, n indicates a refractive index, σ indicates a Boltzmann constant, Φ indicates a phase function, and Ω indicates a fixed angle; standard k-ε models for solving turbulent gas flowing are:

$$\begin{matrix}\frac{\partial ( ρ k )}{\partial t} + \frac{\partial ( ρ {ku}_{i} )}{\partial {x}_{i}} = \frac{\partial }{\partial {x}_{i}} [ ( μ + \frac{{u}_{i}}{{σ}_{k}} ) ] + {G}_{k} \\ + {G}_{b} - ρε - {Y}_{M} + {S}_{k}\end{matrix} , \qquad ( 7 )$$

$$\begin{matrix}\frac{\partial ( ρ E )}{\partial t} + \frac{\partial ( ρ E {u}_{l} )}{\partial {x}_{l}} = \frac{\partial }{\partial {x}_{j}} [ ( μ + \frac{{u}_{l}}{{σ}_{E}} ) \frac{{\partial }_{E}}{\partial {x}_{j}} ] \\ + {C}_{1 ε} \frac{ε}{k} ( {G}_{k} + {C}_{3 ε} {G}_{b} ) - {C}_{2 ε} ρ \frac{{ε}^{2}}{k} + {S}_{ε}\end{matrix} , \qquad ( 8 )$$

in which ρ indicates a gas density, k indicates a turbulent energy, uᵢ indicates a speed, xᵢ and xⱼ indicate a coordinate system, and μ indicates a turbulent viscosity; an eddy dissipation conceptual model for solving an interaction between gas flowing and a combustion chemical reaction is as follows:

$$\frac{\partial }{\partial t} ( ρ {Y}_{i} ) + ∇ \cdot ( ρ \vec{v} {Y}_{i} ) = - ∇ \cdot {\vec{J}}_{i} + {R}_{i} + {S}_{i} , \qquad ( 9 )$$

in which Yᵢ indicates a mass fraction of a substance i, \vec{J}ᵢ indicates a diffusion flux of the substance, Rᵢ indicates a net production rate, and Sᵢ indicates an additional production rate; and thermal radiation distribution data obtained after the Fluent simulation is iteratively coupled as an FLIC input, and after a difference of temperature between outputs of the Fluent and the FLIC satisfies a set error, visual fields of temperature, speed and concentration are output.

Optionally, in step 103, simulating the waste heat exchange, the flue gas cleaning and other processes based on Aspen Plus are specifically as follows:
a flue gas temperature and flue gas components output by the FLIC, a hearth temperature output by the Fluent, an MSW ash content obtained based on an assay, as well as a secondary air temperature, a secondary air flow rate and a dose of urea solution as acquired on an industrial site are taken as inputs, where the flue gas components include H₂O, N₂, O₂, H₂, CO, CO₂, CH₄ and S; a combustion process is simulated in the furnace by a Gibbs reactor RGibbs and a denitrification reaction is simulated by a stoichiometric reaction Rstoic1, involving reactions as follows:

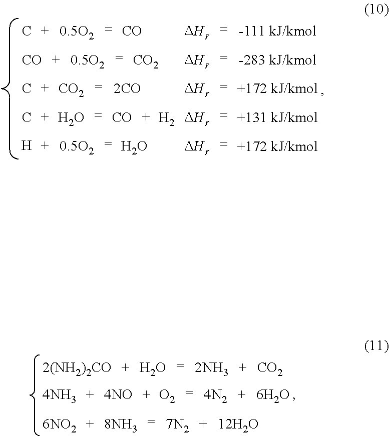

in a stage of heat exchange process in a waste heat boiler, a heat exchange process between the high-temperature flue gas and a superheater and between the high-temperature flue gas and an economizer is simulated using a heat exchanger module for two material flows to obtain a cooled flue gas G1 at a hearth outlet; in a stage of flue gas treatment process, a deacidification process of the flue gas G1 is simulated using the stoichiometric reactor as follows:

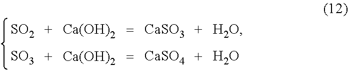

an adsorption process of activated carbon on pollutants such as heavy metals and dioxins in the flue gas is simulated using a mixer module; a bag dust collector is simulated using a component separator module; finally, a process of fly ash entering an ash bin is simulated by a diverter module to in turn obtain a treated flue gas G2; and in a stage of flue gas emission, simulation is performed by a compressor module to obtain a flue gas G3 to enter the atmosphere.
optionally, in step 2, acquiring, based on the module for acquiring simulation mechanism data under multiple operating conditions, simulation mechanism data under multiple operating conditions by means of the whole-process numerical simulation model is specifically as follows:
1 non-manipulated variable and 11 manipulated variables are selected to perform a four-level orthogonal experimental design, wherein the non-manipulated variable is an MSW component, and the manipulated variables include a feed quantity, a grate speed, a primary air temperature 1, a primary air temperature 2, a primary air temperature 3, a primary air flow rate 1, a primary air flow rate 2, a primary air flow rate 3, a primary air flow rate 4, a secondary air temperature and a secondary air flow rate; and the simulation mechanism data under multiple operating conditions are acquired by means of the whole-process numerical simulation model based on the orthogonal experimental design.

Optionally, in step 3, building the exhaust emission model based on the MIMO-LRDT algorithm by means of the module for building the MIMO-LRDT-based exhaust emission model is specifically as follows:
the exhaust emission model including exhaust gases such as CO, CO₂, O₂, SO₂ and NOx is built using a multiple-input multiple-output linear regression decision tree based on the simulation mechanism data under multiple operating conditions, wherein the obtained simulation mechanism data are denoted as

$$D = {\{ {x}_{i} , {y}_{i} \}}_{i = 1}^{64} ∈ {⊔}^{64 \times ( 11 + 5 )} ;$$

the simulation mechanism data are traversed to calculate a mean square error of a target value as follows:

$$\begin{matrix}\begin{matrix}{L}_{k}^{MSE} ( n , i ) = {f}_{MSE} ( {D}_{left} ) + {f}_{MSE} ( {D}_{right} ) \\ = \frac{1}{5} {\sum }_{Targ = 1}^{5} \{ {( ( {y}_{Targ , Left} - {\overline{y}}_{Targ , Left} ) I ( {x}_{i} ∈ {D}_{left} ) )}^{2} + {( ( {y}_{Targ , Right} - {y}_{Targ , Right} ) I ( {x}_{i} ∈ {D}_{right} ) )}^{2} \}\end{matrix} \\ in which {L}_{k}^{MSE} ( n , i )\end{matrix} , \qquad ( 13 )$$

indicates a loss function value of the MSW, and (n,i) indicates an i^{th} feature value of an n^{th} sample in a k^{th} iteration;
a minimum MSE is selected based on a calculation result as a segmentation variable of a first nonleaf node

$$\begin{matrix}{x}_{nonleaf}^{1} as follows : \\ {x}_{1 , nonleaf}^{MD} = min {\{ {L}_{k}^{MSE} ( n , i ) \}}_{k = 1}^{K}\end{matrix} , \qquad ( 14 )$$

the process is repeated, and a minimum number of samples θ is set empirically to obtain (T/2−1) intermediate nodes

$$\{ {x}_{nonleaf}^{1} , {x}_{nonleaf}^{3} … , {x}_{nonleaf}^{T / 2 - 1} \} ;$$

a predicated output of a classification and regression tree (CART) leaf node is calculated using a linear regression method as follows:

$$\begin{matrix}\begin{matrix}{\hat{Y}}_{leaf}^{t} = {X}_{leaf}^{t} {W}_{leaf}^{t} \\ = {X}_{leaf}^{t} [ {w}_{leaf}^{1} , {w}_{leaf}^{2} , {w}_{leaf}^{3} , {w}_{leaf}^{4} , {w}_{leaf}^{5} ]\end{matrix} \\ in which {Y}_{leaf}^{t} , {X}_{leaf}^{t} and {W}_{leaf}^{t}\end{matrix} , \qquad ( 15 )$$

indicate an output, an input and a weight matrix of a t^{th} leaf node, respectively;
weight vectors are obtained and classified for solving a class of overdetermined matrix equations with regularized least squares loss function as follows:

$$J ( {W}_{leaf}^{t} ) = {\frac{1}{2} [ \begin{matrix}( {‖ {X}_{leaf}^{t} {w}_{leaf}^{1} - {y}_{leaf}^{1} ‖}_{2}^{2} + λ {‖ {w}_{leaf}^{1} ‖}_{2}^{2} ) \\ ( {‖ {X}_{leaf}^{t} {w}_{leaf}^{2} - {y}_{leaf}^{1} ‖}_{2}^{2} + λ {‖ {w}_{leaf}^{2} ‖}_{2}^{2} ) \\ ( {‖ {X}_{leaf}^{t} {w}_{leaf}^{3} - {y}_{leaf}^{1} ‖}_{2}^{2} + λ {‖ {w}_{leaf}^{3} ‖}_{2}^{2} ) \\ ( {‖ {X}_{leaf}^{t} {w}_{leaf}^{4} - {y}_{leaf}^{1} ‖}_{2}^{2} + λ {‖ {w}_{leaf}^{4} ‖}_{2}^{2} ) \\ ( {‖ {X}_{leaf}^{t} {w}_{leaf}^{5} - {y}_{leaf}^{1} ‖}_{2}^{2} + λ {‖ {w}_{leaf}^{5} ‖}_{2}^{2} )\end{matrix} ]}^{T} , \qquad ( 16 )$$

in which λ indicates the value is a coefficient of regular term, and λ≥0, a gradient of a loss function pair

$${w}_{leaf}^{t}$$

is expressed as:

$$\begin{matrix}\frac{\partial J ( {W}_{leaf}^{t} )}{\partial {( {w}_{leaf}^{t} )}^{T}} = \frac{\partial }{\partial {( {w}_{leaf}^{t} )}^{T}} ( {( {X}_{leaf}^{t} {w}_{leaf}^{t} - {y}_{leaf}^{t} )}^{T} ( {X}_{leaf}^{t} {w}_{leaf}^{t} - \\ {y}_{leaf}^{t} ) + {λ ( {w}_{leaf}^{t} )}^{T} ( {w}_{leaf}^{t} ) ) \\ = {( {X}_{leaf}^{t} )}^{T} {X}_{leaf}^{t} {w}_{leaf}^{t} - {( {X}_{leaf}^{t} )}^{T} {y}_{leaf}^{t} + h ( {w}_{leaf}^{t} )\end{matrix} , \qquad ( 17 )$$

$$supposing \frac{\partial J ( {W}_{leaf}^{t} )}{\partial {( {w}_{leaf}^{t} )}^{T}} = 0 , then :$$

$${w}_{leaf}^{f} = {( {( {X}_{leaf}^{f} )}^{T} {X}_{leaf}^{f} + λ I )}^{- 1} {( {X}_{leaf}^{f} )}^{T} {y}_{leaf}^{f} , \qquad ( 18 )$$

a predicted value of a leaf node is calculated according to the obtained weight vectors; and considering all leaf nodes, a MIMO-LRDT model is expressed as:

$$\hat{y} = {f}_{M IMO - LRDT} ( x ) . \qquad ( 19 )$$

According to the specific embodiments provided by the present invention, the present invention discloses the following technical effects: the present invention provides the system and method for exhaust emission modeling and analysis of the municipal solid waste incineration process; the system includes a module for building a whole-process numerical simulation model under reference operating conditions by coupling multiple software, a module for acquiring simulation mechanism data under multiple operating conditions, a module for building a MIMO-LRDT-based exhaust emission model, and a module for single/double-factor-based exhaust emission analysis; and the method includes: building, based on the module for building the whole-process numerical simulation model under reference working conditions by coupling multiple software, a whole-process numerical simulation model capable of fitting reference operating conditions on an industrial site; acquiring, based on the module for acquiring simulation mechanism data under multiple operating conditions, simulation mechanism data under multiple operating conditions by means of the whole-process numerical simulation model; building an exhaust emission model based on a MIMO-LRDT algorithm by means of a module for building a MIMO-LRDT-based exhaust emission model; and performing single/double-factor analysis on a mapping relationship between manipulated variables and exhaust emissions concentration based on the exhaust emission model by means of the module for single/double-factor-based exhaust emission analysis. Here, a basis is laid for analyzing the relationship between the manipulated variables of “air and material distribution” and the exhaust emission gases by means of the whole-process numerical simulation model; the twelve-factor four-level orthogonal experiment is designed and implemented based on the whole-process numerical simulation model, in order to provide support for the building of a data-driven model; a multiple-input multiple-output data-driven model is built using the MIMO-LRDT algorithm by taking the manipulated variables of “air and material distribution” as inputs and CO, CO₂, O₂, SO₂ and NOx as outputs, and it shows certain advantages in model fitting degree and model structure as compared with the comparative algorithm; and the relationship between the manipulated variables and the exhaust emission is analyzed using the single/double-factor strategy and based on the built MIMO-LDRT data-driven model, providing corresponding guidance to the operation optimization of the MSWI process.

### BRIEF DESCRIPTION OF THE DRAWINGS

To describe the technical solutions in the embodiments of the present invention or in the prior art more clearly, the following briefly introduces the accompanying drawings required to be used in the embodiments. Apparently, the accompanying drawings in the following description show merely some embodiments of the present disclosure, and a person of ordinary skill in the art may still derive other drawings from these accompanying drawings without creative efforts.

FIG. 1 shows a schematic flowchart of a municipal solid waste incineration process;

FIG. 2 shows a schematic structural diagram of a system for exhaust emission modeling and analysis of a municipal solid waste incineration process according to an embodiment of the present invention;

FIG. 3 shows a schematic diagram of the results of gas component distribution in a combustion process on a grate;

FIGS. 4A-4C show schematic diagrams of simulation results of a combustion process in a furnace;

FIG. 5A shows a schematic diagram of CO emission resulting from simulation;

FIG. 5B shows a schematic diagram of CO₂ emission resulting from simulation;

FIG. 5C shows a schematic diagram of O₂ emission resulting from simulation;

FIG. 5D shows a schematic diagram of SO₂ emission resulting from simulation;

FIG. 5E shows a schematic diagram of NOx emission resulting from simulation;

FIG. 6A shows a schematic diagram for analysis of feed quantity;

FIG. 6B shows a schematic diagram for analysis of primary air temperature 2;

FIG. 7A shows a schematic diagram for analysis of feed quantity and grate speed;

FIG. 7B shows a schematic diagram for analysis of feed quantity and primary air temperature 1; and

FIG. 8 shows a schematic flowchart of a method for exhaust emission modeling and analysis of a municipal solid waste incineration process according to an embodiment of the present invention.

### DETAILED DESCRIPTION OF THE EMBODIMENTS

An object of the present invention is to provide a system and method for exhaust emission modeling and analysis of a municipal solid waste incineration process, to enable the exhaust emission modeling and analysis of the municipal solid waste incineration process.

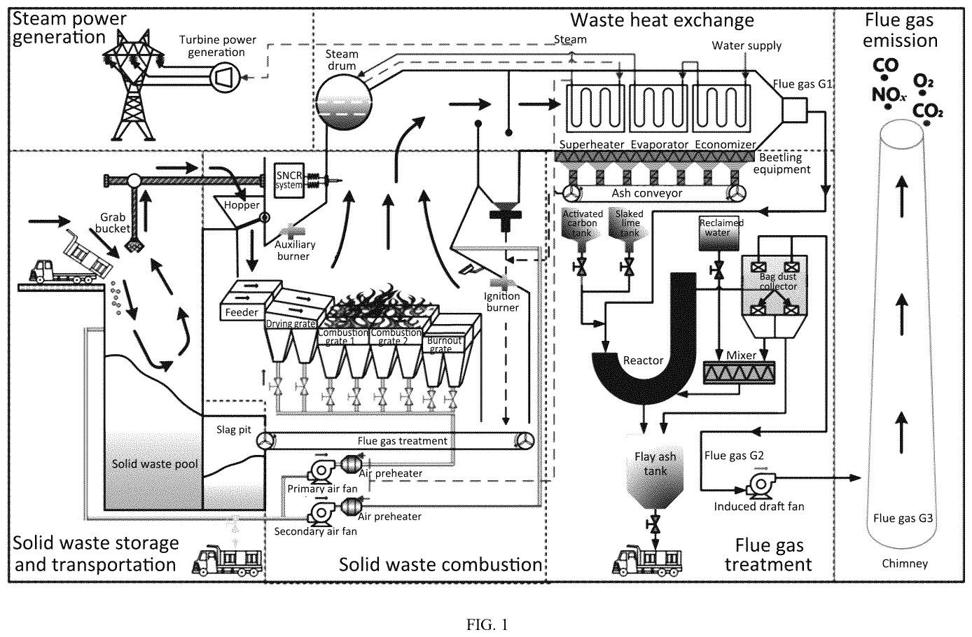

To make the above objects, features and advantages of the present invention more obvious and easier to understand, the present invention will be further described in detail below in conjunction with the accompanying drawings and particular embodiments. The municipal solid waste incineration process is shown in FIG. 1.

Based on the current process and control status of an MSWI plant, the present invention builds a whole-process numerical simulation model and a data-driven model by taking the feed quantity, primary air temperature, primary air flow rate, secondary air temperature and secondary air flow rate as key manipulated variables.

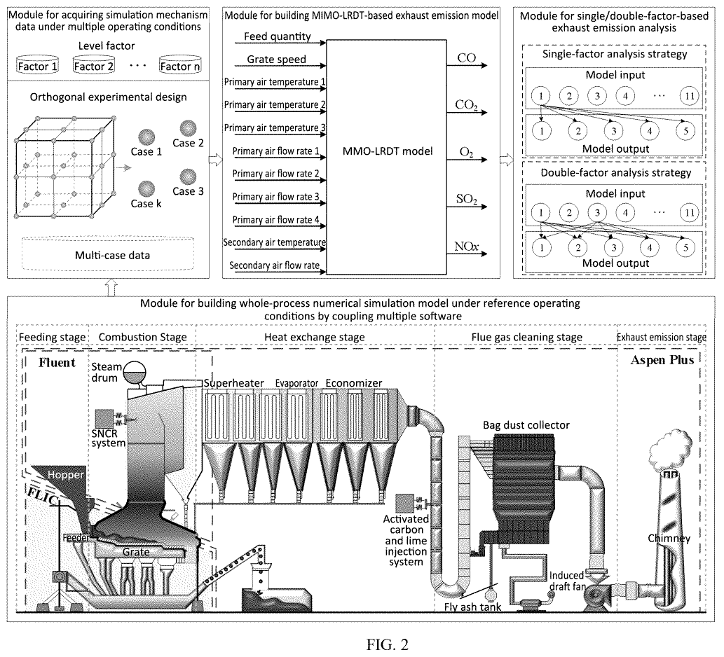

As shown in FIG. 2, an embodiment of the present invention provides a system for exhaust emission modeling and analysis of a municipal solid waste incineration process. The system includes: a module for building a whole-process numerical simulation model under reference operating conditions by coupling multiple software, a module for acquiring simulation mechanism data under multiple operating conditions, a module for building a MIMO-LRDT-based exhaust emission model, and a module for single/double-factor-based exhaust emission analysis, wherein the module for building the whole-process numerical simulation model under reference operating conditions by coupling multiple software is connected to the module for acquiring simulation mechanism data under multiple operating conditions, the module for acquiring simulation mechanism data under multiple operating conditions is connected to the module for building the MIMO-LRDT-based exhaust emission model, the module for building the MIMO-LRDT-based exhaust emission model is connected to the module for single/double-factor-based exhaust emission analysis;

The module for building the whole-process numerical simulation model under reference operating conditions by coupling multiple software is configured to: build a whole-process numerical simulation model capable of fitting reference operating conditions on an industrial site by simulating a solid phase combustion process on a grate with FLIC, simulating a gas phase combustion process in a hearth with Fluent, and simulating waste heat exchange, flue gas cleaning and other stages with Aspen Plus.

The module for acquiring simulation mechanism data under multiple operating conditions is configured to: perform an orthogonal experimental design for the manipulated variables of partial “air and material distribution”, and acquire simulation mechanism data under multiple operating conditions based on the above numerical simulation model under reference operating conditions.

The module for building the MIMO-LRDT-based exhaust emission model is configured to: build an exhaust emission model based on a MIMO-LRDT algorithm by taking the manipulated variables of “air and material distribution” as inputs.

The module for single/double-factor-based exhaust emission analysis is configured to: perform single/double-factor analysis on a mapping relationship between manipulated variable and exhaust emissions concentration based on the above exhaust emission model, in order to support the control strategy for the industrial site.

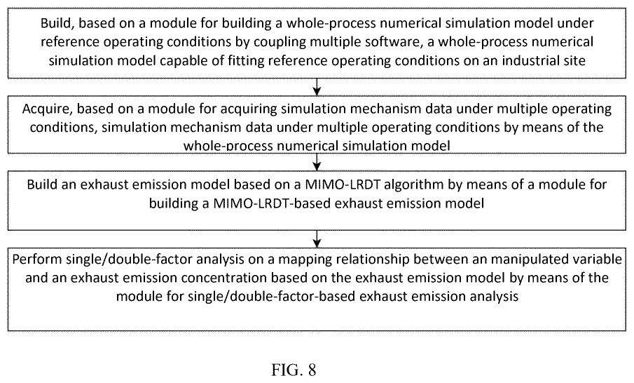

As shown in FIG. 8, the present invention further provides a method for exhaust emission modeling and analysis of a municipal solid waste incineration process, which is applied to the system for exhaust emission modeling and analysis of the municipal solid waste incineration process as described above. The method includes the steps of:
step 1: building, based on a module for building a whole-process numerical simulation model under reference operating conditions by coupling multiple software, a whole-process numerical simulation model capable of fitting reference working conditions on an industrial site;
step 2: acquiring, based on a module for acquiring simulation mechanism data under multiple operating conditions, simulation mechanism data under multiple operating conditions by means of the whole-process numerical simulation model;
step 3: building an exhaust emission model based on a MIMO-LRDT algorithm by means of a module for building a MIMO-LRDT-based exhaust emission model; and
step 4: performing single/double-factor analysis on a mapping relationship between manipulated variables and exhaust emissions concentration based on the exhaust emission model by means of the module for single/double-factor-based exhaust emission analysis.

In step 1: building, based on the module for building the whole-process numerical simulation model under reference operating conditions by coupling multiple software, the whole-process numerical simulation model capable of fitting reference operating conditions on the industrial site specifically includes the steps of:
step 101: simulating a solid phase combustion process on a grate based on FLIC;
step 102: simulating a gas phase combustion process in a hearth based on Fluent; and
step 103: simulating waste heat exchange, flue gas cleaning and other processes based on Aspen Plus.

In step 101, simulating the solid phase combustion process on the grate based on the FLIC is specifically as follows.

The solid phase combustion process on the grate is simulated by means of FLIC under the premise that the fuel on the grate is a homogeneous porous medium with the porosity unchanged during combustion, the flowing of particles in the furnace is not considered, a grate bed is regarded as moving forward at a constant velocity, MSWs consist of moisture, volatiles, fixed carbon and ash, and CO, CO₂, CH₄, H₂, H₂O, NO, HCN, NH₃, N₂ and O₂ are only considered as gas phase components. Here, a solid-phase MSW combustion model, a basic conservation equation and a component transfer and thermal radiation conversion equation are involved.

A solid phase MSW combustion process includes stages of water evaporation, volatile component precipitation, volatile component combustion, and coke oxidation, in which MSW is pushed by a feeder to the grate and undergo high-temperature thermal radiation in a furnace and from a furnace wall to gradually evaporate water at a rate of:

$${R}_{evp} = \{ \begin{matrix}{S}_{a} {h}_{s} ( {C}_{w , s} - {C}_{w , g} ) , & {T}_{s} < 100 ° C . \\ {Q}_{cr} / {H}_{envp} , & {T}_{s} = 100 ° C .\end{matrix} , \qquad ( 1 )$$

in which Rₑᵥₚ indicates a water evaporation rate, Sₐ indicates a particle surface area, hₛ indicates a convective mass transfer coefficient, C_{w,s} and C_{w,g} indicate a moisture content in the MSW and in a mixed gas respectively, Q_{cr} indicates absorbed heat in radiation and convective heat transfer processes, Hₑᵥₚ indicates absorbed heat required for water evaporation, and Tₛ indicates an MSW temperature; after the water evaporation is completed, the MSW reaches a temperature for volatile component precipitation, and a process of releasing main components is as follows:

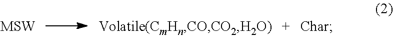

a volatile gas is mixed with air and then combusted, with corresponding combustion reactions as follows:

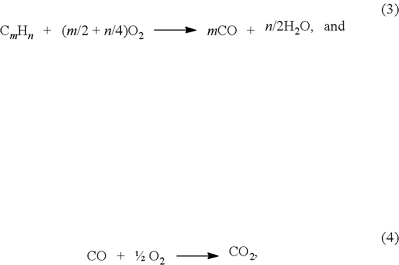

with a combustion rate being a minimum value between a kinetic rate and a mixing rate; and the MSW gradually turns into coke along with the volatile component precipitation, and further react with air to produce CO and CO₂ as follows:

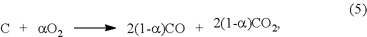

in which α indicates a stoichiometric coefficient, and 0.5≤α≤1.

In step 102, simulating the gas phase combustion process in the hearth based on Fluent is specifically as follows:
by taking an FLIC output as a boundary condition of Fluent numerical simulation, a combustion component CmHn is substituted with CH₄ in the Fluent, and a gas phase component combustion equation is discretized and solved by using a second order upwind format and a SIMPLE algorithm, with a thermal radiation DO model as follows:

$$∇ \cdot ( I ( \vec{r} , \vec{s} ) \vec{s} ) + ( a + {σ}_{s} ) I ( \vec{r} , \vec{s} ) = a {n}^{2} \frac{σ {T}^{4}}{π} + \frac{{σ}_{s}}{4 π} {\int }_{0}^{4 π} I ( \vec{r} , \vec{s} ) Φ ( \vec{s} , {\vec{s}}^{′} ) d {Ω}^{′} , \qquad ( 6 )$$

in which I indicates a radiation intensity, \vec{r} and \vec{s} indicate a position vector and a direction vector respectively, a indicates an absorption coefficient, σₛ indicates a diffusion coefficient, n indicates a refractive index, σ indicates a Boltzmann constant, Φ indicates a phase function, and Ω′ indicates a fixed angle; standard k-ε models for solving turbulent gas flowing are:

$$\frac{\partial ( ρ k )}{\partial t} + \frac{\partial ( ρ k {u}_{i} )}{\partial {x}_{i}} = \frac{\partial }{\partial {x}_{j}} [ ( μ + \frac{{u}_{i}}{{σ}_{k}} ) ] + {G}_{k} + {G}_{b} - ρε - {Y}_{M} + {S}_{k} , \qquad ( 7 )$$

$$\frac{\partial ( ρε )}{\partial t} + \frac{\partial ( ρε {u}_{i} )}{\partial {x}_{i}} = \frac{\partial }{\partial {x}_{j}} [ ( μ + \frac{{u}_{i}}{{σ}_{ε}} ) \frac{\partial ε}{\partial {x}_{j}} ] + {C}_{1 ε} \frac{ε}{k} ( {G}_{k} + {C}_{3 ε} {G}_{b} ) - {C}_{2 ε} ρ \frac{{ε}^{2}}{k} + {S}_{ε} , \qquad ( 8 )$$

in which ρ indicates a gas density, k indicates a turbulent energy, uᵢ indicates a speed, xᵢ and xⱼ indicate a coordinate system, and μ indicates a turbulent viscosity; an eddy dissipation conceptual model for solving an interaction between gas flowing and a combustion chemical reaction is as follows:

$$\frac{\partial }{\partial t} ( ρ {Y}_{i} ) + ∇ \cdot ( ρ \vec{v} {Y}_{i} ) = - ∇ \cdot {\vec{J}}_{i} + {R}_{i} + {S}_{i} , \qquad ( 9 )$$

in which Yᵢ indicates a mass fraction of a substance i, \vec{J}ᵢ indicates a diffusion flux of the substance, Rᵢ indicates a net production rate, and Sᵢ indicates an additional production rate; and thermal radiation distribution data obtained after the Fluent simulation is iteratively coupled as an FLIC input, and after a difference of temperature between outputs of the Fluent and the FLIC satisfies a set error, visual fields of temperature, speed and concentration are output.

In step 103, simulating the waste heat exchange, the flue gas cleaning and other processes based on Aspen Plus are specifically as follows.

It is assumed that all reactions occurring in the furnace can reach equilibrium, the temperature and pressure in the furnace are constant, the MSW ash is an inert component that is not involved in any reaction, the influence of MSW particle size on the combustion reaction is ignored, and the loss and leakage of pressure and gas are not considered. Based on this, the flue gas temperature and components resulting from FLIC simulation, the hearth temperature resulting from Fluent simulation, and the process data (involving the MSW ash content, secondary air flow rate, secondary air temperature, urea solution, water supply to the economizer, calcium hydroxide solution, activated carbon, and reclaimed water) sourced from the actual industrial site are input into the Aspen Plus to simulate MSW storage and incineration, heat exchange in waste heat boiler, flue gas treatment and emission, and other stages.

In a stage of MSW storage and incineration process, a flue gas temperature and flue gas components (including H₂O, N₂, O₂, H₂, CO, CO₂, CH₄ and S) output by the FLIC, a hearth temperature output by the Fluent, an MSW ash content obtained based on an assay, as well as a secondary air temperature, a secondary air flow rate and a dose of urea solution as acquired on an industrial site are taken; and a combustion process is simulated in the furnace by a Gibbs reactor RGibbs and a denitrification reaction is simulated by a stoichiometric reaction Rstoic1, involving reactions as follows:

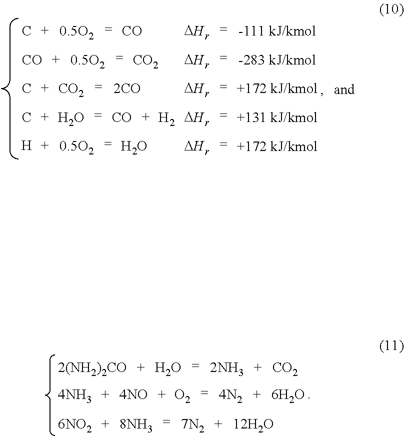

In a stage of heat exchange process in a waste heat boiler, a heat exchange process between the high-temperature flue gas and a superheater and between the high-temperature flue gas and an economizer is simulated using a heat exchanger module for two material flows to obtain a cooled flue gas G1 at a hearth outlet; in a stage of flue gas treatment process, a deacidification process of the flue gas G1 is simulated using the stoichiometric reactor as follows:

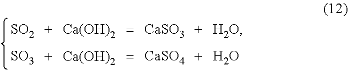

An adsorption process of activated carbon on pollutants such as heavy metals and dioxins in the flue gas is simulated using a mixer module; a bag dust collector is simulated using a component separator module; finally, a process of fly ash entering an ash bin is simulated by a diverter module to in turn obtain a treated flue gas G2; and in a stage of flue gas emission, simulation is performed by a compressor module to obtain a flue gas G3 to enter the atmosphere.

In step 2, acquiring, based on the module for acquiring simulation mechanism data under multiple operating conditions, simulation mechanism data under multiple operating conditions by means of the whole-process numerical simulation model is specifically as follows.

Based on the above multi-software-coupled simulation strategy combined with the process of an MSWI plant in Beijing, 12 factors including 1 non-manipulated variable (MSW components) and 11 manipulated variables (including feed quantity, grate speed, primary air temperature 1, primary air temperature 2, primary air temperature 3, primary air flow rate 1, primary air flow rate 2, primary air flow rate 3, primary air flow rate 4, secondary air temperature and secondary air flow rate) in total were selected for the four-level orthogonal experimental design, with the factor value at each level shown in Table 1.

TABLE 1
Values at each factor level in experimental design

| | Principal | Subordinate | Number of level(s) | | | |
|---|---|---|---|---|---|---|
| No. | factor | factor | 1 | 2 | 3 | 4 |
| 1 | MSW | Moisture | 21.5 | 36 | 46.65 | 56.12 |
| | components | Volatile | 32.8 | 32 | 20.9 | 23.88 |
| | | components | | | | |
| | | Fixed | 37.7 | 8.2 | 15.5 | 5 |
| | | carbon | | | | |
| | | Ash | 8 | 23.8 | 16.95 | 15 |
| | | C | 68.73 | 50.2 | 50.53 | 57.83 |
| | | H | 3.25 | 5.8 | 7.33 | 7.93 |
| | | O | 27.05 | 42.3 | 39.61 | 30.82 |

| | | | | | |
|---|---|---|---|---|---|
| 2 | Feed quantity | 580 | 680 | 780 | 880 |
| 3 | Grate speed | 10 | 20.6 | 31.4 | 42 |
| 4 | Primary air temperature 1 | 343.15 | 386.48 | 429.81 | 473.15 |
| 5 | Primary air temperature 2 | 343.15 | 386.48 | 429.81 | 473.15 |
| 6 | Primary air temperature 3 | 343.15 | 386.48 | 429.81 | 473.15 |
| 7 | Primary air flow rate 1 | 8000 | 13300 | 18600 | 24000 |
| 8 | Primary air flow rate 2 | 8000 | 18666 | 29332 | 40000 |
| 9 | Primary air flow rate 3 | 12000 | 13333 | 14666 | 16000 |
| 10 | Primary air flow rate 4 | 2000 | 2666 | 3332 | 4000 |
| 11 | Secondary air temperature | 423.15 | 439.82 | 456.49 | 473.15 |
| 12 | Secondary air flow rate | 19330 | 26336.7 | 33343.4 | 40350 |

Based on the above experimental design, 64 set of experimental schemes were obtained, and the whole-process numerical simulation model was used to implement the experiment based on multi-software coupling to obtain the simulation mechanism data under multiple operating conditions.

In step 3, building the exhaust emission model based on the MIMO-LRDT algorithm by means of the module for building the MIMO-LRDT-based exhaust emission model is specifically as follows.

The exhaust emission model including exhaust gases such as CO, CO₂, O₂, SO₂ and NOx is built using a multiple-input multiple-output linear regression decision tree based on the simulation mechanism data under multiple operating conditions, wherein the obtained simulation mechanism data are denoted as

$$D = {( {x}_{i} , {y}_{i} )}_{i = 1}^{64} ∈ {R}^{64 \times ( 11 + 5 )} ;$$

the simulation mechanism data are traversed to calculate a mean square error of a target value as follows:

$$\begin{matrix}{L}_{k}^{MSE} ( n , i ) = {f}_{MSE} ( {D}_{right} ) + {f}_{MSE} ( {D}_{right} ) \\ = \frac{1}{5} {\sum }_{Targ = 1}^{5} \{ {( ( {y}_{Targ , Left} - {\overline{y}}_{Targ , Left} ) I ( {x}_{i} ∈ {D}_{left} ) )}^{2} + \\ {( ( {y}_{Targ , Right} - {\overline{y}}_{Tar , Right} ) I ( {x}_{i} ∈ {D}_{right} ) )}^{2} \}\end{matrix} , \qquad ( 13 )$$

$$in which {L}_{k}^{M S E} ( n , i )$$

indicates a loss function value of the MSE, and (n,i) indicates an ith feature value of an nth sample in a kth iteration;
a minimum MSE is selected based on a calculation result as a segmentation variable of a first nonleaf node

$${x}_{nonleaf}^{1} as follows :$$

$${x}_{1 , nonleaf}^{M D} = min {\{ {L}_{k}^{M S E} ( n , i ) \}}_{k = 1}^{K} , \qquad ( 14 )$$

the process is repeated, and a minimum number of samples θ is set empirically to obtain (T/2−1) intermediate nodes

$$\{ {x}_{nonleaf}^{1} , {x}_{nonleaf}^{3} … , {x}_{nonleaf}^{T / 2 - 1} \} ;$$

a predicated output of a CART leaf node is calculated using a linear regression method as follows:

$$\begin{matrix}{\hat{Y}}_{leaf}^{t} = {X}_{leaf}^{t} {W}_{leaf}^{t} \\ = {X}_{leaf}^{t} [ {w}_{leaf}^{1} , {w}_{leaf}^{2} , {w}_{leaf}^{3} , {w}_{leaf}^{4} , {w}_{leaf}^{5} ]\end{matrix} , \qquad ( 15 )$$

$$in which {\hat{Y}}_{leaf}^{t} = {X}_{leaf}^{t} and {W}_{leaf}^{t}$$

indicate an output, an input and a weight matrix of a tth leaf node, respectively;
weight vectors are obtained and classified for solving a class of overdetermined matrix equations with regularized least squares loss function as follows:

$$J ( {W}_{leaf}^{t} ) = {\frac{1}{2} [ \begin{matrix}( ‖ {X}_{leaf}^{t} {w}_{leaf}^{1} - {y}_{leaf}^{1} {‖}_{2}^{2} + λ ‖ {w}_{leaf}^{1} {‖}_{2}^{2} \\ ( ‖ {X}_{leaf}^{t} {w}_{leaf}^{2} - {y}_{leaf}^{2} {‖}_{2}^{2} + λ ‖ {w}_{leaf}^{2} {‖}_{2}^{2} \\ ( ‖ {X}_{leaf}^{t} {w}_{leaf}^{3} - {y}_{leaf}^{3} {‖}_{2}^{2} + λ ‖ {w}_{leaf}^{3} {‖}_{2}^{2} \\ ( ‖ {X}_{leaf}^{t} {w}_{leaf}^{4} - {y}_{leaf}^{4} {‖}_{2}^{2} + λ ‖ {w}_{leaf}^{4} {‖}_{2}^{2} \\ ( ‖ {X}_{leaf}^{t} {w}_{leaf}^{5} - {y}_{leaf}^{5} {‖}_{2}^{2} + λ ‖ {w}_{leaf}^{5} {‖}_{2}^{2}\end{matrix} ]}^{T} , \qquad ( 16 )$$

in which λ indicates the value is a coefficient of regular term, and λ≥0, a gradient of a loss function pair

$${w}_{leaf}^{t}$$

is expressed as:

$$\begin{matrix}\frac{\partial J ( {W}_{leaf}^{t} )}{\partial {( {w}_{leaf}^{t} )}^{T}} = \frac{\partial }{\partial {( {w}_{leaf}^{t} )}^{T}} ( {( {X}_{leaf}^{t} {w}_{leaf}^{t} - {y}_{leaf}^{t} )}^{T} ( {X}_{leaf}^{t} {w}_{leaf}^{t} - \\ {y}_{leaf}^{t} ) + λ {( {w}_{leaf}^{t} )}^{T} ( {w}_{leaf}^{t} ) ) \\ = {( {X}_{leaf}^{t} )}^{T} {X}_{leaf}^{t} {w}_{leaf}^{t} - {( {X}_{leaf}^{t} )}^{T} {y}_{leaf}^{t} + h ( {w}_{leaf}^{t} )\end{matrix} , \qquad ( 17 )$$

$$supposing \frac{\partial I ( {W}_{leaf}^{t} )}{\partial {( {w}_{leaf}^{t} )}^{T}} = 0 , then :$$

$${w}_{leaf}^{t} = {( {( {X}_{leaf}^{t} )}^{T} {X}_{leaf}^{t} + λ I )}^{- 1} {( {X}_{leaf}^{t} )}^{T} {y}_{leaf}^{t} , \qquad ( 18 )$$

a predicted value of a leaf node is calculated according to the obtained weight vectors; and considering all leaf nodes, a MIMO-LRDT model is expressed as:

$$\hat{y} = {f}_{M IMO - LRDT} ( x ) . \qquad ( 19 )$$

The above manipulated variables were subjected to single/double-factor analysis based on the built MIMO-LRDT-based exhaust emission model, in order to explore the influence of the manipulated variables such as feed quantity, grate speed, primary air temperature 1, primary air temperature 2, primary air temperature 3, primary air flow rate 1, primary air flow rate 2, primary air flow rate 3, primary air flow rate 4, secondary air temperature and secondary air flow rate on CO, CO₂, O₂, SO₂ and NOx in the exhaust emission.

The present invention provides an embodiment for simulation verification. Numerical simulation was carried out based on an MSWI power plant, and the parameters of MSW components and the operating parameters of the incineration furnace under reference operating conditions are shown in Tables 2 and 3, respectively.

TABLE 2
Parameters of MSW components

| | Numerical | |
|---|---|---|
| Component | value | Unit |
| Moisture | 49.70 | ar |
| Volatile | 32.22 | ar |
| components | | |
| Fixed | 7.82 | ar |
| carbon | | |
| Ash | 10.26 | ar |
| C | 65.62 | daf |
| H | 8.09 | daf |
| O | 24.93 | daf |
| N | 1.12 | daf |
| S | 0.11 | daf |
| Q_{ar, net} | 8350 | kJ/kg |

TABLE 3
Operating parameters of incineration furnace
under reference operating conditions

| | | Numerical | |
|---|---|---|---|
| Parameter | | value | |
| Grate speed | — | 8 | m/h |
| Feed | — | 29.25 | t/h |
| quantity | | | |
| Primary air | — | 500 | K |
| temperature | | | |
| Primary air | Air volume | 16320 | Nm³/h |
| flow rate | of drying | | |
| | grate | | |
| | Air volume | 34000 | Nm³/h |
| | of Stage-1 | | |
| | combustion | | |
| | grate | | |
| | Air volume | 13600 | Nm³/h |
| | of Stage-2 | | |
| | combustion | | |
| | grate | | |
| | Air volume | 4080 | Nm³/h |
| | of burnout | | |
| | grate | | |
| Secondary | — | 300 | K |
| air | | | |
| temperature | | | |
| Secondary | — | 7000 | Nm³/h |
| air flow | | | |
| rate | | | |
| Urea | — | 166 | kg/h |
| Ca(OH)₂ | — | 873.92 | kg/h |
| Activated | — | 17.8 | kg/h |
| carbon | | | |
| Reclaimed | — | 642.71 | kg/h |
| water | | | |
| Water | — | 64000 | kg/h |
| supply for | | | |
| economizer | | | |

Results and discussions on building of whole-process numerical simulation model under reference operating conditions by coupling multiple software

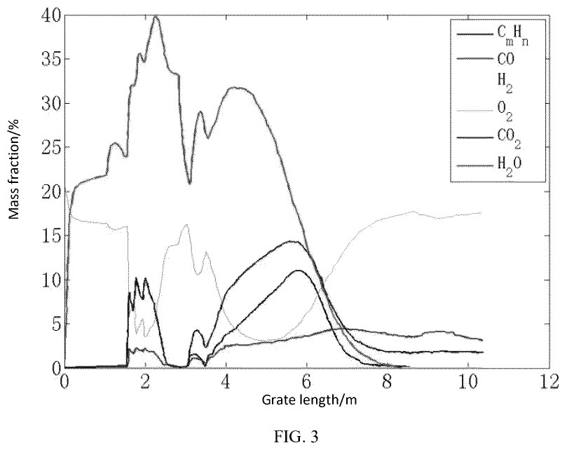

The distribution of gas components in the combustion process on the grate based on FLIC simulation is shown in FIG. 3. From FIG. 3, it can be seen that when the MSWs gradually move on the grate, the water evaporation rate increases under the action of thermal radiation at high temperature, such that the mass fraction of H₂O in the flue gas increases before 2.0 m, decreases briefly after reaching a peak, increases briefly between 4.0 m and 5.0 m due to H₂O carried by primary air, and finally decreases to 0 around 8.0 m with the combustion process proceeds; the mass fractions of CO, CmHn and H₂ increase with the increase in volatile component release rate; and CO₂ is produced by the mixed combustion of volatile components, coke and O₂, such that the mass fraction of CO₂ increases as the mass fraction of O₂ decreases.

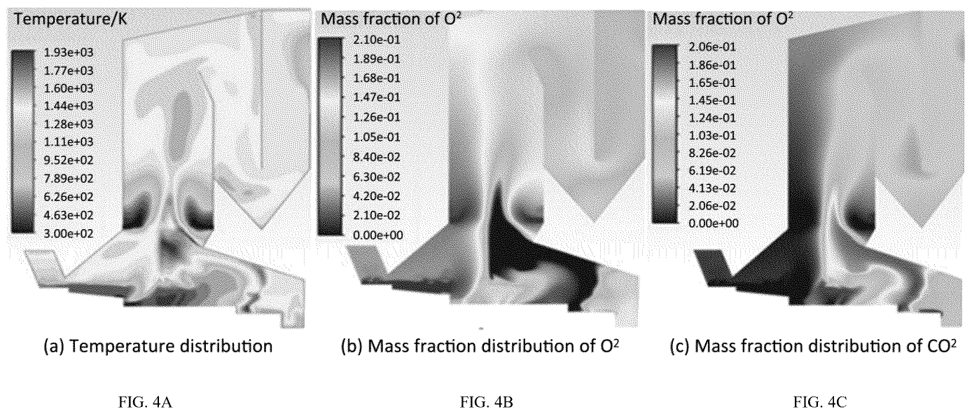

The cloud charts of the temperature distribution and the mass fractions of O₂ and CO₂ in the combustion process in the hearth based on Fluent simulation are shown in FIGS. 4A-4C. From FIGS. 4A-4C, it can be seen that a large amount of O₂ is consumed during the combustion process to produce CO₂, and accordingly, the temperature and the mass fraction of CO₂ are the highest and the mass fraction of O₂ is the lowest in the middle of the hearth; the flue gas gradually flows to the furnace outlet along the furnace wall, resulting in a gradual decrease in temperature compared with that in the middle of the hearth; and meanwhile, the combustion is basically completed during the flowing of the flue gas, resulting in increased mass fraction of O₂ and decreased mass fraction of CO₂.

The numerical simulation results of waste heat exchange, flue gas cleaning and other processes simulated based on Aspen Plus are shown in Table 4.

TABLE 4
Numerical simulation results of Aspen Plus

Flue gas G3

| | Mass flow | Concentration |
|---|---|---|
| Parameter | (kg/h) | (%) |
| O₂ | 1594.89 | 9.33 |
| CO₂ | 1104.60 | 6.46 |

| | |
|---|---|
| Temperature | 157.70 |

(° C.)

From Table 4, it can be seen that the concentrations of O₂ and CO₂ in the flue gas G3 may reach the national standard level as the physical and chemical reactions occur in the flue gas treatment stage.

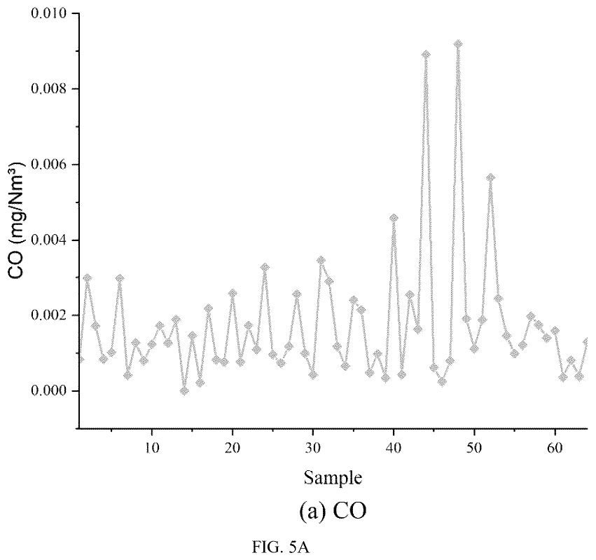

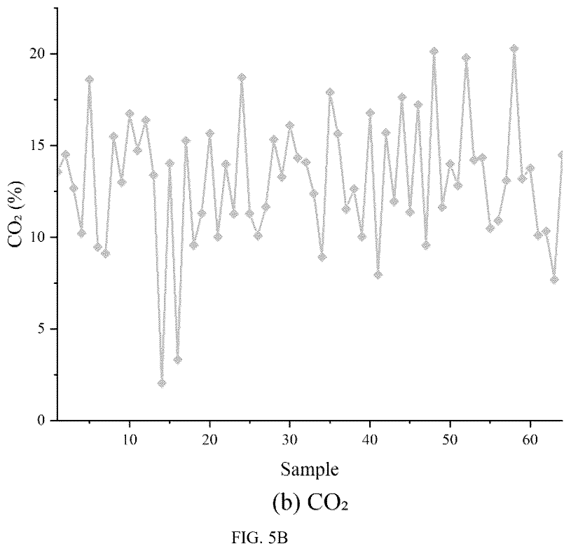

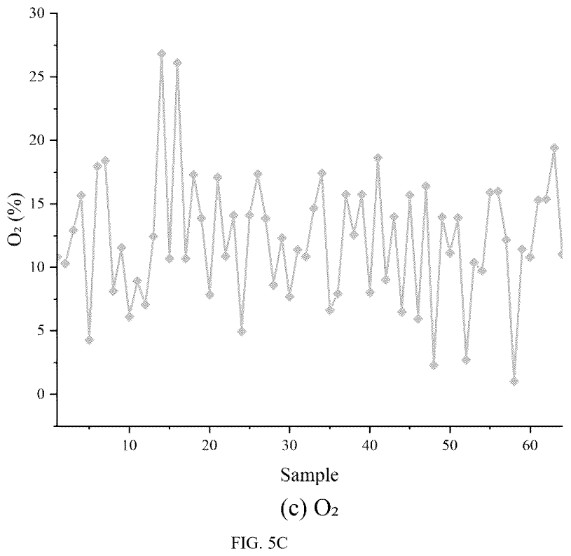

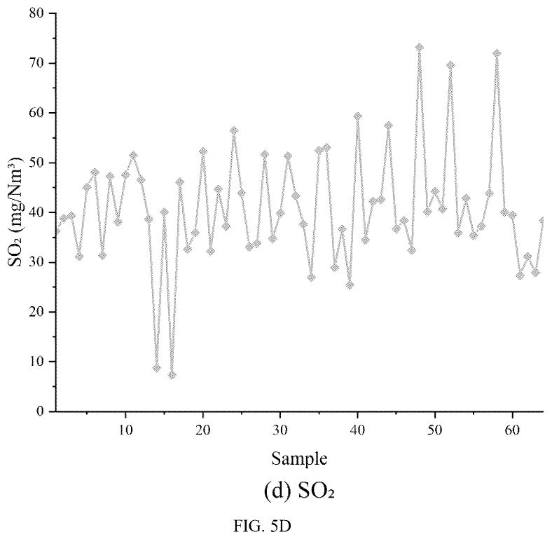

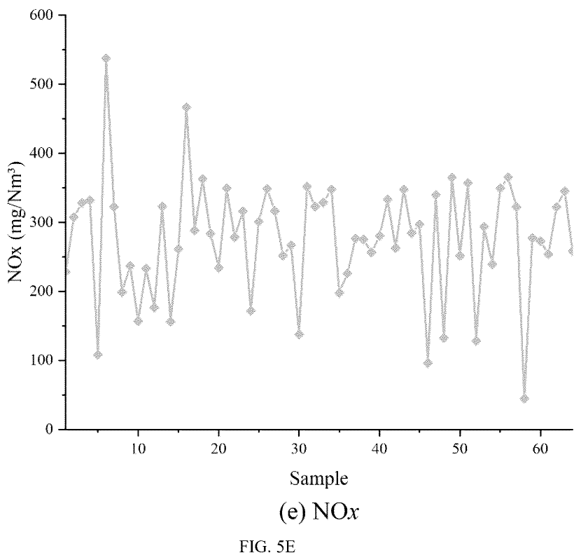

Results and discussions on acquisition of simulation mechanism data under multiple operating conditions: the orthogonal experiment is implemented based on the multi-software-coupled full-process numerical simulation model under reference operating conditions to obtain 64 sets of experimental data, which are converted based on the unit on the actual industrial site to finally obtain the simulated exhaust emission results as shown in FIGS. 5A-5E. From the incineration mechanism, it can be seen that CO₂ is produced by the mixed combustion of volatile components, coke and O₂, and the emission concentration of CO₂ is inversely proportional to the emission concentrations of O₂ an CO. This mechanism is embodied in FIGS. 5A, 5B and 5C, which thus demonstrates the effectiveness of the multi-software-coupled whole-process numerical simulation model under reference operating conditions as established by the present invention and the designed orthogonal experiment. However, in FIG. 5C, the acquired simulation mechanism data show that the emission concentrations of O₂ at sampling points 14 and 16 exceed the standard oxygen content (21%) in the air. Consequently, these data are considered abnormal and need to be rejected during the process of modeling.

Results and discussions on building of MIMO-LRDT-based exhaust emission model: the results from the above module for acquiring simulation mechanism data under multiple operating conditions are preprocessed to obtain 62 sets of data for building a MIMO-LRDT model; in order to verify the effectiveness of the model built by the present invention, a backpropagation neural network (BPNN), a decision tree (CART) and a random forest (RF) are used to build a multiple-input single-output model for comparative experiments, where the parameters of the MIMO-LRDT model are set as follows: minimum number of samples: 5, and coefficient of regular term: 0.5; the parameter of a CART model is set as follows: minimum number of samples: 5; the parameters of a RF model are set as follows: minimum number of samples: 5, number of decision trees: 100; and the parameters of a GBDT model are set as follows: minimum number of samples: 5, number of iterations: 5, and learning rate: 0.5.

The root mean square error (RMSE) is used as an index to evaluate the performances of the above models, with a calculation formula as follows:

$$RMSE = \sqrt{\frac{1}{N} {\sum }_{i = 1}^{N} ( {y}^{i} - {y}^{i} )} , \qquad ( 20 )$$

in which ŷⁱ and yⁱ indicate the predicted and truth values of the model; and N indicates the number of samples.

The RMSE statistical results of the model test sets are shown in Table 5.

TABLE 5
RMSE statistical results of model test sets

| NO | MIMO-LRDT | CART | RF | GBDT |
|---|---|---|---|---|
| CO | 2.12E−03 | 1.62E−03 | 1.78E−03 | 1.90E−03 |
| CO₂ | 2.91E+00 | 4.11E+00 | 2.89E+00 | 2.99E+00 |
| O₂ | 4.20E+00 | 4.87E+00 | 4.32E+00 | 4.11E+00 |
| SO₂ | 1.20E+01 | 1.39E+01 | 9.06E+00 | 7.14E+00 |
| NOx | 6.48E+01 | 8.34E+01 | 7.25E+01 | 7.51E+01 |
| Average | 1.68E+01 | 2.13E+01 | 1.77E+01 | 1.79E+01 |
| Value | | | | |

From Table 5, it can be seen that differences are present in the output statistical results of different model test sets, where the MIMO-LRDT model shows the best effect from the statistical results of NOx and mean value; the CART model shows the best effect from the statistical results of CO output; the RF model shows the best statistical results in terms of CO₂ output; the GBDT model shows the best effect from the statistical results of O₂ and SO₂ outputs. The exhaust emission model established by the present invention has the minimum mean error.

The MIMO-LRDT model proposed in the present invention is improved based on the CART model and converts the mean output of a leaf node converted into a weight, which allows for smoother model output while improving the model accuracy, such that this model is more suitable to be applied as a controlled object model. At the same time, compared with the multiple-input single-output model established by the comparative method, the MIMO-LRDT model proposed by the present invention shows certain advantages in the statistical results, which demonstrates its effectiveness.

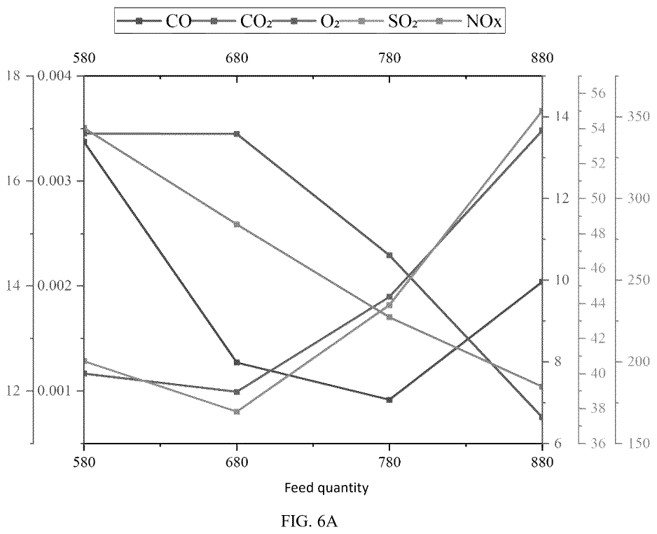

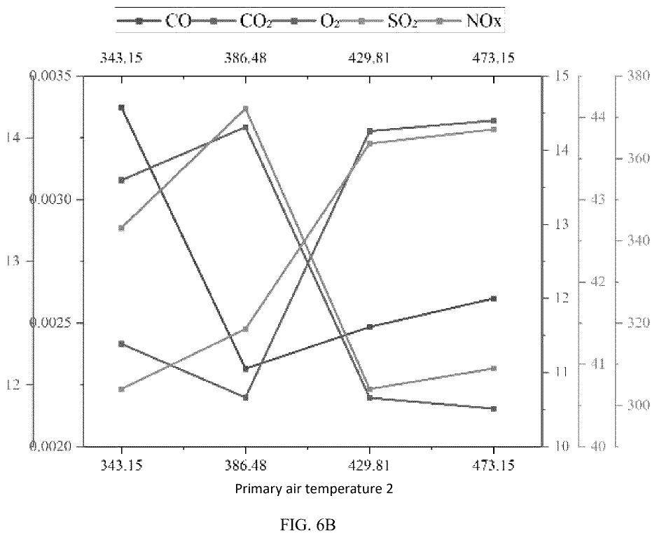

Results and discussions on single/double-factor-based exhaust emission analysis: for the built MIMO-LRDT model, the feed quantity and primary air temperature are changed within a set range for single-factor analysis by fixing other manipulated variables to values under reference operating condition. The change curves of different gas concentrations in the exhaust are shown in FIGS. 6A-6B.

From FIG. 6A, it can be seen that with the gradual increase of feed quantity, the emission concentrations of O₂ and NOx gradually decrease, the emission concentration of CO increases first and then decreases, and CO₂ and SO₂ show an overall increasing trend. From FIG. 6B, it can be seen that with the gradual increase of the primary air temperature 2, the emission concentrations of CO, CO₂ and SO₂ decrease first and then increase, and at this point, O₂ and NOx show a trend of increasing first and then decreasing. In summary, the change trend of the exhaust emission concentration is basically in line with the perceived mechanism of the MSWI process.

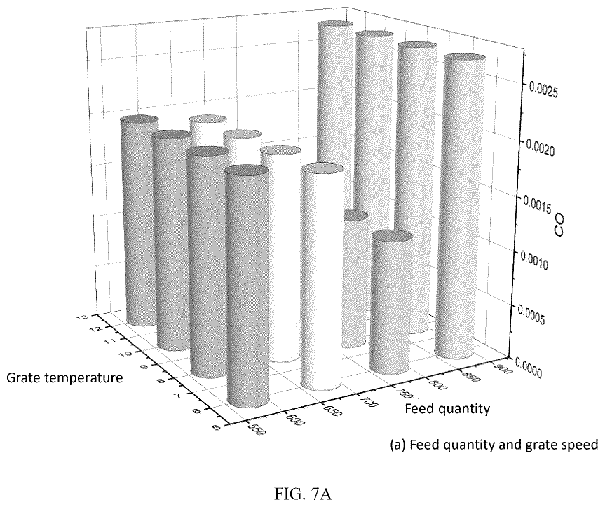

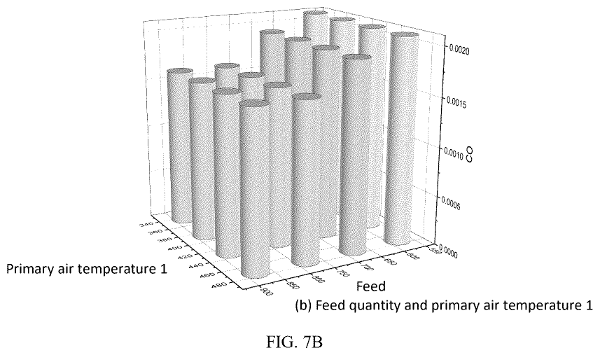

Similarly, the double-factor analysis is performed by simultaneously changing the grate speed and the feed quantity as well as the primary air temperature 1 and the feed quantity within a certain range. The change curves of the emission concentration of CO in the exhaust are shown in FIGS. 7A-7B.

From FIGS. 7A-7B, it can be seen that compared with the feed quantity, the grate speed and the primary air temperature 1 show a little influence on the emission concentration of CO in the exhaust. Therefore, it is necessary to choose the feed quantity reasonably, in order to increase the economic benefits of the MSWI power plant while ensuring that the exhaust emission meets the standards.

The present invention provides the system and method for exhaust emission modeling and analysis of the municipal solid waste incineration process; the system includes a module for building a whole-process numerical simulation model under reference operating conditions by coupling multiple software, a module for acquiring simulation mechanism data under multiple operating conditions, a module for building a MIMO-LRDT-based exhaust emission model, and a module for single/double-factor-based exhaust emission analysis; the method includes: building, based on the module for building the whole-process numerical simulation model under reference operating conditions by coupling multiple software, a whole-process numerical simulation model capable of fitting reference operating conditions on an industrial site; acquiring, based on the module for acquiring simulation mechanism data under multiple operating conditions, simulation mechanism data under multiple operating conditions by means of the whole-process numerical simulation model; building an exhaust emission model based on a MIMO-LRDT algorithm by means of a module for building a MIMO-LRDT-based exhaust emission model; and performing single/double-factor analysis on a mapping relationship between an manipulated variable and an exhaust emission concentration based on the exhaust emission model by means of the module for single/double-factor-based exhaust emission analysis. Here, a basis is laid for analyzing the relationship between the manipulated variables of “air and material distribution” and the exhaust emission gases by means of the whole-process numerical simulation model; the twelve-factor four-level orthogonal experiment is designed and implemented based on the whole-process numerical simulation model, in order to provide support for the building of a data-driven model; a multiple-input multiple-output data-driven model is built using the MIMO-LRDT algorithm by taking the manipulated variables of “air and material distribution” as inputs and CO, CO₂, O₂, SO₂ and NOx as outputs, and it shows certain advantages in model fitting degree and model structure as compared with the comparative algorithm; and the relationship between the manipulated variables and the exhaust emission is analyzed using the single/double-factor strategy and based on the built MIMO-LDRT data-driven model, providing corresponding guidance to the operation optimization of the MSWI process.

Specific examples are used in the present invention to explain the principles and implementations of the present invention. The descriptions of the above embodiments are only for the purpose of helping understand the method and core idea of the present invention. Meanwhile, for a person of ordinary skills in the art, there will be changes in the specific implementation and the application scope according to the concept of the present invention. In summary, the content of the Specification should not be understood as limiting the present invention.

What is claimed is:

1. A system for exhaust emission modeling and analysis of a municipal solid waste incineration process, comprising: a module for building a whole-process numerical simulation model under reference operating conditions by coupling multiple software, a module for acquiring simulation mechanism data under multiple operating conditions, a module for building a multiple-input multiple-output local regression decision tree (MIMO-LRDT)-based exhaust emission model, and a module for single/double-factor-based exhaust emission analysis, wherein the module for building the whole-process numerical simulation model under the reference operating conditions by coupling the multiple software is connected to the module for acquiring the simulation mechanism data under the multiple operating conditions, the module for acquiring the simulation mechanism data under the multiple operating conditions is connected to the module for building the MIMO-LRDT-based exhaust emission model, and the module for building the MIMO-LRDT-based exhaust emission model is connected to the module for the single/double-factor-based exhaust emission analysis;
the module for building the whole-process numerical simulation model under the reference operating conditions by coupling the multiple software is configured to build the whole-process numerical simulation model for fitting the reference operating conditions on an industrial site;
the module for acquiring the simulation mechanism data under the multiple operating conditions is configured to enable the whole-process numerical simulation model to acquire the simulation mechanism data under the multiple operating conditions;
the module for building the MIMO-LRDT-based exhaust emission model is configured to build an exhaust emission model based on a MIMO-LRDT algorithm; and
the module for the single/double-factor-based exhaust emission analysis is configured to perform single/double-factor analysis on a mapping relationship between an manipulated variable and an exhaust emission concentration based on the exhaust emission model.

2. A method for exhaust emission modeling and analysis of a municipal solid waste incineration process, applied to the system for exhaust emission modeling and analysis of the municipal solid waste incineration process according to claim 1, and comprising:
step 1: building, based on a module for building a whole-process numerical simulation model under reference operating conditions by coupling multiple software, the whole-process numerical simulation model for fitting the reference operating conditions on an industrial site;
step 2: acquiring, based on a module for acquiring simulation mechanism data under multiple operating conditions, the simulation mechanism data under the multiple operating conditions by the whole-process numerical simulation model;
step 3: building an exhaust emission model based on a MIMO-LRDT algorithm by a module for building a MIMO-LRDT-based exhaust emission model; and
step 4: performing single/double-factor analysis on a mapping relationship between an manipulated variable and an exhaust emission concentration based on the exhaust emission model by a module for single/double-factor-based exhaust emission analysis.

3. The method for exhaust emission modeling and analysis of the municipal solid waste incineration process according to claim 2, wherein in step 1, building, based on the module for building the whole-process numerical simulation model under the reference operating conditions by coupling the multiple software, the whole-process numerical simulation model for fitting the reference operating conditions on the industrial site comprises:
step 101: simulating a solid phase combustion process on a grate based on fuel layer interface code (FLIC);
step 102: simulating a gas phase combustion process in a hearth based on Fluent; and
step 103: simulating waste heat exchange, flue gas cleaning and other processes based on Aspen Plus.

4. The method for exhaust emission modeling and analysis of the municipal solid waste incineration process according to claim 3, wherein in step 101, simulating the solid phase combustion process on the grate based on the FLIC is implemented as follows:
the solid phase combustion process on the grate is simulated by the FLIC, wherein a solid-phase municipal solid waste (MSW) combustion model, a basic conservation equation, and a component transfer and thermal radiation conversion equation are involved;
a solid phase MSW combustion process comprises stages of water evaporation, volatile component precipitation, volatile component combustion, and coke oxidation, wherein MSW is pushed by a feeder to the grate and undergo high-temperature thermal radiation in a furnace and from a furnace wall to gradually evaporate water at a rate of:
$${R}_{evp} = \{ \begin{matrix}{S}_{a} {h}_{s} ( {C}_{w , s} - {C}_{w , g} ) & {T}_{s} < 100 °C . \\ {Q}_{cr} / {H}_{evp} & {T}_{s} = 100 °C .\end{matrix} , \qquad ( 1 )$$
wherein Rₑᵥₚ indicates a water evaporation rate, Sₐ indicates a particle surface area, indicates a coefficient of convective mass transfer, C_{w,s} and hₛ C_{w,g} indicate a moisture content in the MSW and a moisture content in a mixed gas respectively, Q_{cr} indicates absorbed heat in radiation and convective heat transfer processes, Hₑᵥₚ indicates absorbed heat required for water evaporation, and Tₛ indicates an MSW temperature; after the water evaporation is completed, the MSW reaches a temperature for the volatile component precipitation, and a process of releasing main components is as follows: 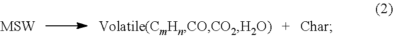
a volatile gas is mixed with air and then combusted, with corresponding combustion reactions as follows: 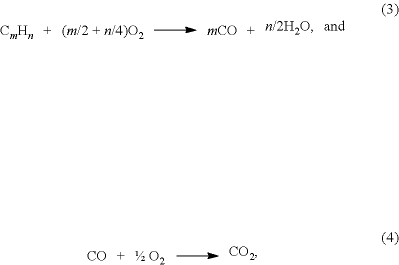
with a combustion rate being a minimum value between a kinetic rate and a mixing rate; and the MSW gradually turns into coke along with the volatile component precipitation, and further react with air to produce CO and CO₂ as follows: 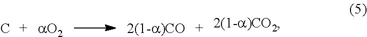
wherein α indicates a stoichiometric coefficient, and 0.5≤α≤1.

5. The method for exhaust emission modeling and analysis of the municipal solid waste incineration process according to claim 4, wherein in step 102, simulating the gas phase combustion process in the hearth based on the Fluent is implemented as follows:
by taking an FLIC output as a boundary condition of Fluent numerical simulation, a combustion component CmHn is substituted with CH₄ in the Fluent, and a gas phase component combustion equation is discretized and solved by using a second order upwind format and a semi-implicit method for pressure-linked equations (SIMPLE) algorithm, with a thermal radiation discrete ordinates (DO) model as follows:
$$\begin{matrix}∇ \cdot ( I ( \vec{r} , \vec{s} ) \vec{s} ) + ( a + {σ}_{s} ) I ( \vec{r} , \vec{s} ) = {an}^{2} \frac{σ {T}^{4}}{π} \\ + \frac{{σ}_{s}}{4 π} {\int }_{0}^{4 π} I ( \vec{r} , \vec{s} ) Φ ( \vec{s} , {\vec{s}}^{′} ) d {Ω}^{′}\end{matrix} , \qquad ( 6 )$$
wherein I indicates a radiation intensity, \vec{r} and \vec{s} indicate a position vector and a direction vector respectively, a indicates an absorption coefficient, σₛ indicates a diffusion coefficient, n indicates a refractive index, σ indicates a Boltzmann constant, indicates a phase function, and Ω′ indicates a fixed angle; standard k-ε models for solving turbulent gas flowing are:
$$\begin{matrix}\frac{\partial ( ρ k )}{\partial t} + \frac{\partial ( ρ {ku}_{i} )}{\partial {x}_{i}} = \frac{\partial }{\partial {x}_{j}} [ ( μ + \frac{{u}_{i}}{{σ}_{k}} ) ] + {G}_{k} \\ + {G}_{b} - ρε - {Y}_{M} + {S}_{k}\end{matrix} , and \qquad ( 7 )$$
$$\begin{matrix}\frac{\partial ( ρε )}{\partial t} + \frac{\partial ( ρε {u}_{l} )}{\partial {x}_{i}} = \frac{\partial }{\partial {x}_{j}} [ ( μ + \frac{{u}_{i}}{{σ}_{ε}} ) \frac{\partial ε}{\partial {x}_{j}} ] \\ + {C}_{1 ε} \frac{ε}{k} ( {G}_{k} + {C}_{3 ε} {G}_{b} ) - {C}_{2 ε} ρ \frac{{ε}^{2}}{k} + {S}_{ε}\end{matrix} , \qquad ( 8 )$$
wherein ρ indicates a gas density, k indicates a turbulent energy, uᵢ indicates a speed, xᵢ and xⱼ indicate a coordinate system, and A indicates a turbulent viscosity; an eddy dissipation conceptual model for solving an interaction between gas flowing and a combustion chemical reaction is as follows:
$$\frac{\partial }{\partial t} ( ρ {Y}_{i} ) + ∇ \cdot ( ρ \vec{v} {Y}_{i} ) = - ∇ \cdot {\vec{J}}_{i} + {R}_{i} + {S}_{i} , \qquad ( 9 )$$
wherein Yᵢ indicates a mass fraction of a substance i, \vec{J}ᵢ indicates a diffusion flux of the substance, Rᵢ indicates a net production rate, and Sᵢ indicates an additional production rate; and thermal radiation distribution data obtained after the Fluent numerical simulation is iteratively coupled as an FLIC input, and after a difference of temperature between outputs of the Fluent and the FLIC satisfies a set error, visual fields of temperature, speed and concentration are output.

6. The method for exhaust emission modeling and analysis of the municipal solid waste incineration process according to claim 5, wherein in step 103, simulating the waste heat exchange, the flue gas cleaning and other processes based on the Aspen Plus are implemented as follows:
a flue gas temperature and flue gas components output by the FLIC, a hearth temperature output by the Fluent, an MSW ash content obtained based on an assay, as well as a secondary air temperature, a secondary air flow rate and a dose of urea solution as acquired on an industrial site are taken as inputs, wherein the flue gas components comprise H₂O, N₂, O₂, H₂, CO, CO₂, CH₄ and S; a combustion process is simulated in the furnace by a Gibbs reactor RGibbs and a denitrification reaction is simulated by a stoichiometric reaction Rstoic1, involving reactions as follows: 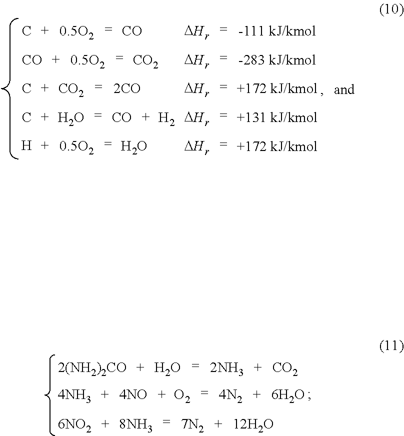
in a stage of heat exchange process in a waste heat boiler, a heat exchange process between a high-temperature flue gas and a superheater and between the high-temperature flue gas and an economizer is simulated using a heat exchanger module for two material flows to obtain a cooled flue gas G1 at a hearth outlet; in a stage of flue gas treatment process, a deacidification process of the cooled flue gas G1 is simulated using a stoichiometric reactor as follows: 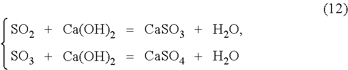
an adsorption process of activated carbon on pollutants comprising heavy metals and dioxins in the cooled flue gas G1 is simulated using a mixer module; a bag dust collector is simulated using a component separator module; finally, a process of fly ash entering an ash bin is simulated by a diverter module to in turn obtain a treated flue gas G2; and in a stage of flue gas emission, simulation is performed by a compressor module to obtain a flue gas G3 to enter the atmosphere.

7. The method for exhaust emission modeling and analysis of the municipal solid waste incineration process according to claim 6, wherein in step 2, acquiring, based on the module for acquiring the simulation mechanism data under the multiple operating conditions, the simulation mechanism data under the multiple operating conditions by the whole-process numerical simulation model is implemented as follows:
1 non-manipulated variable and 11 manipulated variables are selected to perform a four-level orthogonal experimental design, wherein the 1 non-manipulated variable is an MSW component, and the 11 manipulated variables comprise a feed quantity, a grate speed, a primary air temperature 1, a primary air temperature 2, a primary air temperature 3, a primary air flow rate 1, a primary air flow rate 2, a primary air flow rate 3, a primary air flow rate 4, a secondary air temperature and a secondary air flow rate; and the simulation mechanism data under the multiple operating conditions are acquired by the whole-process numerical simulation model based on the four-level orthogonal experimental design.

8. The method for exhaust emission modeling and analysis of the municipal solid waste incineration process according to claim 7, wherein in step 3, building the exhaust emission model based on the MIMO-LRDT algorithm by the module for building the MIMO-LRDT-based exhaust emission model is implemented as follows:
the exhaust emission model comprising exhaust gases such as CO, CO₂, O₂, SO₂ and NOx is built using a multiple-input multiple-output linear regression decision tree based on the simulation mechanism data under the multiple operating conditions, wherein the simulation mechanism data are denoted as
$$D = {( {x}_{i} , {y}_{i} )}_{i = 1}^{64} ∈ {R}^{64 \times ( 11 + 5 )} ;$$
the simulation mechanism data are traversed to calculate a mean square error of a target value as follows:
$$\begin{matrix}\begin{matrix}{L}_{k}^{MSE} ( n , i ) = {f}_{MSE} ( {D}_{left} ) + {f}_{MSE} ( {D}_{right} ) \\ = \frac{1}{5} {\sum }_{Targ = 1}^{5} \{ {( ( {y}_{Targ , Left} - {\overline{y}}_{Targ , Left} ) I ( {x}_{i} ∈ {D}_{left} ) )}^{2} + {( ( {y}_{Targ , Right} - {\overline{y}}_{Targ , Right} ) I ( {x}_{i} ∈ {D}_{right} ) )}^{2} \}\end{matrix} \\ wherein {L}_{k}^{MSE} ( n , i )\end{matrix} , \qquad ( 13 )$$
indicates a loss function value of the MSW, and (n,i) indicates an i^{th} feature value of an n^{th} sample in a k^{th} iteration;
a minimum MSE is selected based on a calculation result as a segmentation variable of a first nonleaf node
$$\begin{matrix}{x}_{nonleaf}^{1} as follows : \\ {x}_{1 , nonleaf}^{MD} = min {\{ {L}_{k}^{MSE} ( n , i ) \}}_{k = 1}^{K}\end{matrix} , \qquad ( 14 )$$
the process is repeated, and a minimum number of samples θ is set empirically to obtain (T/2−1) intermediate nodes
$$\{ {x}_{nonleaf}^{1} , {x}_{nonleaf}^{3} … , {x}_{nonleaf}^{T / 2 - 1} \}$$
a predicated output of a classification and regression tree (CART) leaf node is calculated using a linear regression method as follows:
$$\begin{matrix}\begin{matrix}{\hat{Y}}_{leaf}^{t} = {X}_{leaf}^{t} {W}_{leaf}^{t} \\ = {X}_{leaf}^{t} [ {w}_{leaf}^{1} , {w}_{leaf}^{2} , {w}_{leaf}^{3} , {w}_{leaf}^{4} , {w}_{leaf}^{5} ]\end{matrix} \\ wherein {Y}_{leaf}^{t} , {X}_{leaf}^{t} and {W}_{leaf}^{t}\end{matrix} , \qquad ( 15 )$$
indicate an output, an input and a weight matrix of a tth leaf node, respectively;
weight vectors are obtained and classified for solving a class of overdetermined matrix equations with regularized least squares loss function as follows:
$$J ( {W}_{leaf}^{t} ) = {\frac{1}{2} [ \begin{matrix}( {‖ {X}_{leaf}^{t} {w}_{leaf}^{1} - {y}_{leaf}^{1} ‖}_{2}^{2} + λ {‖ {w}_{leaf}^{1} ‖}_{2}^{2} ) \\ ( {‖ {X}_{leaf}^{t} {w}_{leaf}^{2} - {y}_{leaf}^{2} ‖}_{2}^{2} + λ {‖ {w}_{leaf}^{2} ‖}_{2}^{2} ) \\ ( {‖ {X}_{leaf}^{t} {w}_{leaf}^{3} - {y}_{leaf}^{3} ‖}_{2}^{2} + λ {‖ {w}_{leaf}^{3} ‖}_{2}^{2} ) \\ ( {‖ {X}_{leaf}^{t} {w}_{leaf}^{4} - {y}_{leaf}^{4} ‖}_{2}^{2} + λ {‖ {w}_{leaf}^{4} ‖}_{2}^{2} ) \\ ( {‖ {X}_{leaf}^{t} {w}_{leaf}^{5} - {y}_{leaf}^{5} ‖}_{2}^{2} + λ {‖ {w}_{leaf}^{5} ‖}_{2}^{2} )\end{matrix} ]}^{T} , \qquad ( 16 )$$
wherein λ indicates a value is a coefficient of regular term, and λ≥0, a gradient of a loss function pair
$${w}_{leaf}^{t}$$
is expressed as:
$$\begin{matrix}\frac{\partial J ( {W}_{leaf}^{t} )}{\partial {( {w}_{leaf}^{t} )}^{T}} = \frac{\partial }{\partial {( {w}_{leaf}^{t} )}^{T}} ( {( {X}_{leaf}^{t} {w}_{leaf}^{t} - {y}_{leaf}^{t} )}^{T} ( {X}_{leaf}^{t} {w}_{leaf}^{t} - {y}_{leaf}^{t} ) + {λ ( {w}_{leaf}^{t} )}^{T} ( {w}_{leaf}^{t} ) ) \\ = {( {X}_{leaf}^{t} )}^{T} {X}_{leaf}^{t} {w}_{leaf}^{t} - {( {X}_{leaf}^{t} )}^{T} {y}_{leaf}^{t} + {λ}_{FT} ( {w}_{leaf}^{t} )\end{matrix} , \qquad ( 17 )$$
$$\begin{matrix}supposing \frac{\partial J ( {W}_{leaf}^{t} )}{\partial {( {w}_{leaf}^{t} )}^{T}} = 0 , then : \\ {w}_{leaf}^{t} = {( {( {X}_{leaf}^{t} )}^{T} {X}_{leaf}^{t} + λ I )}^{- 1} {( {X}_{leaf}^{t} )}^{T} {y}_{leaf}^{t}\end{matrix} , \qquad ( 18 )$$
a predicted value of a leaf node is calculated according to the weight vectors; and considering all leaf nodes, the MIMO-LRDT-based exhaust emission model is expressed as:
$$\hat{y} = {f}_{MIMO - LRDT} ( x ) . \qquad ( 19 )$$
